(19) United States
(12) Patent Application Publication
(10) Pub. No.: US 2026/0040430 A1
(43) Pub. Date: Feb. 5, 2026

(54) ELECTRONIC DEVICE INCLUDING ELECTROSTATIC DISCHARGE PATH

(71) Applicant: Samsung Electronics Co., Ltd., Suwon-si (KR)

(72) Inventors: Sewon OH, Suwon-si (KR); Seongho SON, Suwon-si (KR); Jaekyu LEE, Suwon-si (KR); Jongsung LEE, Suwon-si (KR); Cheolgu JO, Suwon-si (KR); Kiwoong CHA, Suwon-si (KR); Jeongnam CHEON, Suwon-si (KR); Woonghae CHOI, Suwon-si (KR)

(21) Appl. No.: 19/248,946

(22) Filed: Jun. 25, 2025

Related U.S. Application Data
(63) Continuation of application No. PCT/KR2025/008162, filed on Jun. 13, 2025.

(30) Foreign Application Priority Data
Aug. 5, 2024 (KR) 10-2024-0104270
Sep. 9, 2024 (KR) 10-2024-0122121

(51) Int. Cl. H05K 1/02; H05K 5/02; H05K 7/14

(52) U.S. Cl. CPC H05K 1/0213; H05K 5/0226; H05K 7/1427

(57) ABSTRACT

An electronic device is provided. The electronic device includes a first housing including a conductive first side frame, a second housing including a conductive second side frame, a flexible display disposed on the first housing and the second housing, a hinge module rotatably coupled between the first housing and the second housing, and a printed circuit board (PCB) disposed on the first housing or the second housing, the PCB includes a conductive member electrically connected to the conductive first side frame or the conductive second side frame, a signal layer, a ground layer, and an insulation layer, wherein the PCB includes at least one discharge hole recessed from a side (e.g., surface) of the PCB so that the ground layer is visible from an outside and forming a gap between the signal layer or the conductive member and the ground layer.

### CROSS-REFERENCE TO RELATED APPLICATION(S)

This application is a continuation application, claiming priority under 35 U.S.C. § 365(c), of an International application No. PCT/KR2025/008162, filed on Jun. 13, 2025, which is based on and claims the benefit of a Korean patent application number 10-2024-0104270, filed on Aug. 5, 2024, in the Korean Intellectual Property Office, and of a Korean patent application number 10-2024-0122121, filed on Sep. 9, 2024, in the Korean Intellectual Property Office, the disclosure of each of which is incorporated by reference herein in its entirety.

### BACKGROUND

### 1. Field

The disclosure relates to an electronic device including an electrostatic discharge path.

### 2. Description of Related Art

Developments in electronics, information, and communication technologies give rise to integration of various functions into a single electronic device or a portable communication device. For example, smartphones pack the functionalities of a sound player, photographing device, and scheduler, as well as the communication functionality and, on top of that, may implement more various functions by having applications installed thereon.

As smartphones or other personal/portable communication devices spread, users' demand for portability and use convenience is on the rise. For example, a touchscreen display not only serves as an output device of visual information but also provide a virtual keyboard that replaces a mechanical input device (e.g., a button input device). As such, portable communication devices or electronic devices may be made compact while delivering further enhanced applicability (e.g., a larger screen). Flexible displays, e.g., foldable and rollable displays, will be more commercially available, and electronic devices are expected to deliver better portability and use convenience.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide an electronic device including electrostatic discharge path.

Additional aspects will be set forth in part in the description which follows and, in part, will be apparent from the description, or may be learned by practice of the presented embodiments.

In accordance with an aspect of the disclosure, an electronic device is provided. The electronic device incudes a first housing including a conductive first side frame, a second housing including a conductive second side frame, a flexible display disposed on the first housing and the second housing, a hinge module rotatably coupled between the first housing and the second housing, and a printed circuit board (PCB) disposed on the first housing or the second housing, and the PCB including a conductive member electrically connected to the conductive first side frame or the conductive second side frame, a signal layer, a ground layer, and an insulation layer, wherein the PCB includes at least one discharge hole recessed from a side (e.g., surface) of the PCB so that the ground layer is visible from an outside and forming a gap between the signal layer or the conductive member and the ground layer.

In accordance with another aspect of the disclosure, an electronic device is provided. The electronic device includes a first housing including a conductive first side frame, a second housing including a conductive second side frame, a flexible display disposed on the first housing and the second housing, a hinge module rotatably coupled between the first housing and the second housing, and a PCB disposed on the first housing or the second housing, and including a conductive pad electrically connected to the conductive first side frame or the conductive second side frame, a signal layer, a ground layer, and an insulation layer, wherein the ground layer includes a plurality of conductive layers, and wherein at least one of the plurality of conductive layers includes a discharge portion disposed on the same plane as a side (e.g., surface) of the PCB to be visible from an outside.

In accordance with another aspect of the disclosure, an electronic device is provided. The electronic device includes a housing including a conductive side frame, and a PCB disposed on the housing, and including a conductive member electrically connected to a side frame, a signal layer, a ground layer, and an insulation layer, wherein the PCB includes at least one discharge hole recessed from a side (e.g., surface) of the PCB so that the ground layer is visible from an outside and forming a gap between any one of the signal layer or the conductive member and the ground layer.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a block diagram illustrating an electronic device in a network environment according to an embodiment of the disclosure;

FIG. 2 is a view illustrating an unfolded state of an electronic device according to an embodiment of the disclosure;

FIG. 3 is a view illustrating a folded state of an electronic device according to an embodiment of the disclosure;

FIG. 4 is an exploded perspective view illustrating an electronic device according to an embodiment of the disclosure;

FIG. 5A is a plan view illustrating a first housing according to an embodiment of the disclosure;

FIG. 5B is a plan view illustrating a second housing according to an embodiment of the disclosure;

FIG. 6 is a cross-sectional view illustrating an electronic device in an electrostatic discharge (ESD) path according to an embodiment of the disclosure;

FIG. 7 is an enlarged view of portion A of FIG. 6 according to an embodiment of the disclosure;

FIG. 8 is a cross-sectional view illustrating an electronic device in an ESD path according to an embodiment of the disclosure;

FIG. 9A is an enlarged view of portion B of FIG. 8 according to an embodiment of the disclosure;

FIG. 9B is a plan view illustrating a printed circuit board with portion C of FIG. 9A enlarged and viewed from above according to an embodiment of the disclosure;

FIG. 10 is a schematically view illustrating an electronic device in an ESD path according to an embodiment of the disclosure; and

FIG. 11 is a view schematically illustrating a printed circuit board according to an embodiment of the disclosure.

The same reference numerals are used to represent the same elements throughout the drawings.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component side or surface” includes reference to one or more of such sides or surfaces.

The electronic device, according to embodiments of the disclosure may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

An embodiment of the disclosure and terms used therein are not intended to limit the technical features described in the disclosure to specific embodiments, and should be understood to include various modifications, equivalents, or substitutes of the embodiment. With regard to the description of the drawings, similar reference numerals may be used to refer to similar or related elements.

As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

According to an embodiment, each component (e.g., a module or a program) of the above-described components may include a single entity or multiple entities. Some of the plurality of entities may be separately disposed in different components. According to an embodiment, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

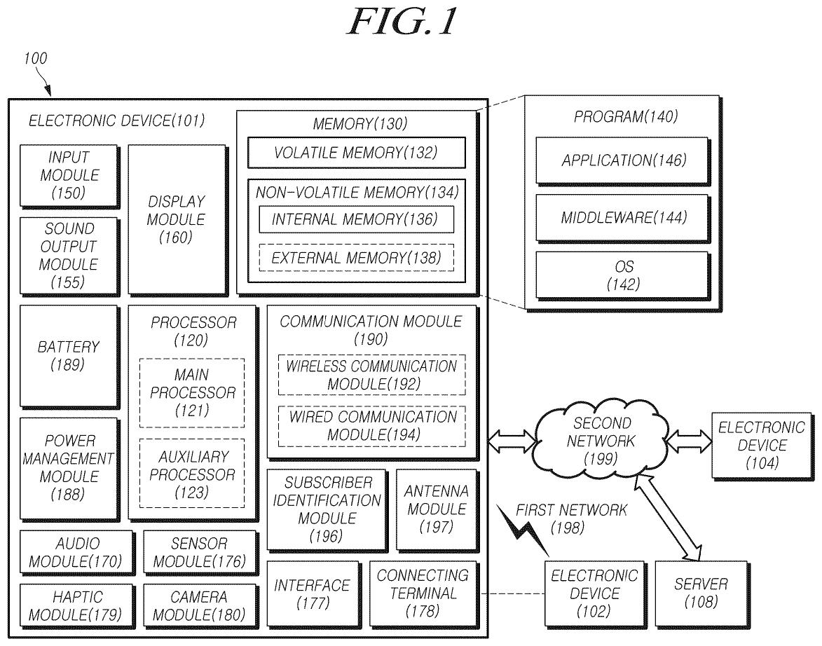

FIG. 1 is a block diagram illustrating an electronic device in a network environment according to an embodiment of the disclosure.

Referring to FIG. 1, an electronic device 101 in a network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. In an embodiment, some (e.g., the sensor module 176, the camera module 180, or the antenna module 197) of the components may be integrated into a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134. The non-volatile memory 134 may include internal memory 136 and external memory 138.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. The sensor module 176 may include, e.g., a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a fifth generation (5G) network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to an embodiment, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, instructions or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102 or 104, or the server 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

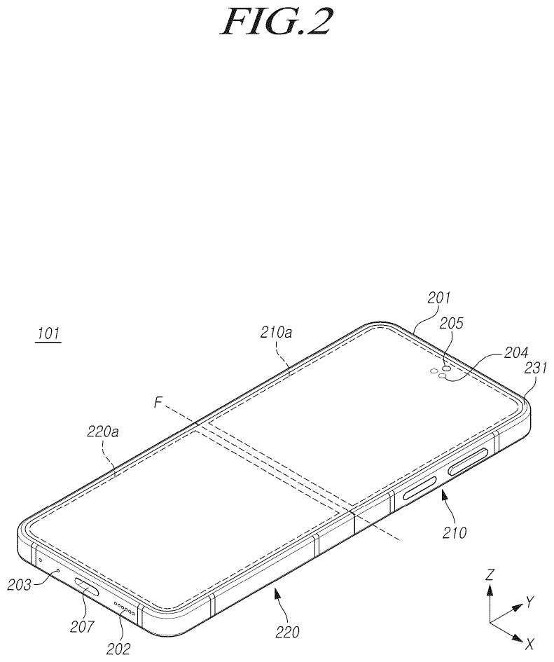

FIG. 2 is a view illustrating an unfolded state of an electronic device according to an embodiment of the disclosure.

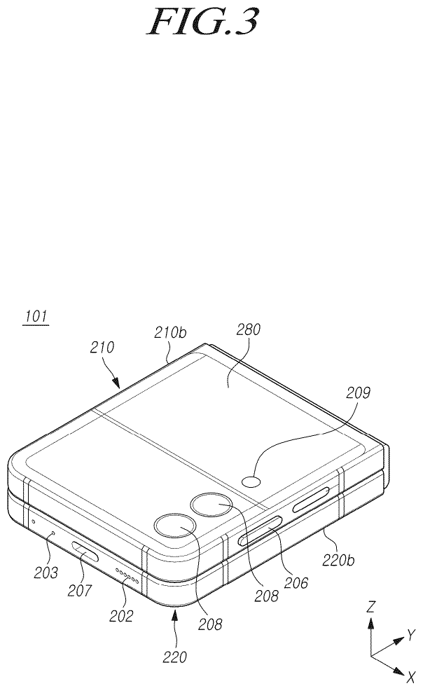

FIG. 3 is a view illustrating a folded state of an electronic device according to an embodiment of the disclosure.

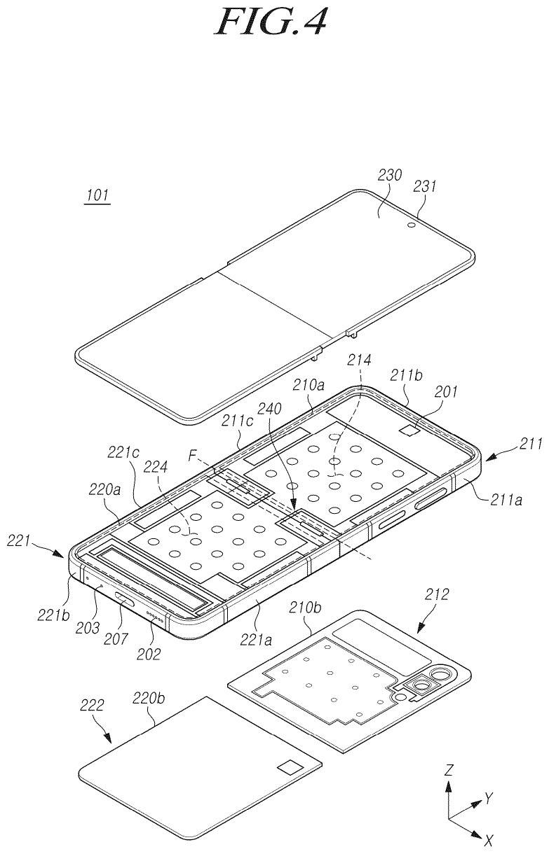

FIG. 4 is an exploded perspective view illustrating an electronic device according to an embodiment of the disclosure.

The electronic device shown in FIGS. 2 to 4 is for illustrative purposes only, and the disclosure is not limited by the drawings. The XYZ coordinate system shown in FIGS. 2 to 4 is for illustrative purposes of describing the layout of the components and does not limit the scope of the claims.

Referring to FIGS. 2-4, the electronic device 101 (e.g., the electronic device 101 of FIG. 1), according to an embodiment, may include at least one pair of housings 210 and 220. The pair of housings 210 and 220 may be rotatably coupled to fold about, e.g., a hinge (e.g., the hinge 240 of FIG. 4) while facing each other.

According to an embodiment, the pair of housings 210 and 220 may include a first housing 210 and a second housing 220. The first housing 210 and the second housing 220 may be disposed on two opposite sides of the folding axis F. An area or side (e.g., edge) of one end of the first housing 210 and an area or side (e.g., edge) of one end of the second housing 220 may be disposed side by side with the hinge 240 interposed therebetween. The first housing 210 and the second housing 220 may have symmetrical shapes with respect to a plane including the folding axis F and extending in the Z-axis direction. The folding axis F may be an axis extending in the X1 direction, formed by the hinge 240.

According to an embodiment, the first housing 210 may have substantially the same length as the second housing 220 (e.g., length in the Y-axis direction), but is not limited thereto. The first housing 210 may have substantially the same width as the second housing 220 (e.g., width in the X-axis direction), but is not limited thereto.

Hereinafter, ‘unfolded state (or flat state)’ or ‘unfolding state’ may refer to a state in which the angle between the first housing 210 and the second housing 220 is substantially 180 degrees. ‘Folded state’ or a ‘folding state’ may refer to a state in which the angle formed between the first housing 210 and the second housing 220 is substantially zero (0) degrees. ‘Intermediate state’ may refer to any state between the unfolded state and the folded state. According to an embodiment, the electronic device 101 may rotate about the hinge 240 such that the first housing 210 and the second housing 220 form an angle from zero (0) degrees to 180 degrees. According to an embodiment, the electronic device 101 may rotate about the hinge 240 such that the first housing 210 and the second housing 220 form an angle from 180 degrees to 360 degrees.

According to an embodiment, the first housing 210 may include a first side 210a and a second side 210b. For example, the first side 210a is provided to face in an upper direction (e.g., +Z-axis direction). The first side 210a may be, e.g., a side (e.g., surface) on which at least a portion of the flexible display 230 is disposed. The first side 210a may refer to, e.g., a virtual side (e.g., surface) overlapping at least a portion of the flexible display 230. For example, the second side 210b may be provided to face in a lower direction (e.g., −Z1-axis direction). The second side 210b may be, e.g., a side (e.g., surface) on which the sub display 280 is disposed. The second side 210b may be, e.g., a side (e.g., surface) on which the first rear cover 212 is disposed. The second side 210b may be parallel to the first side 210a. The second side 210b may refer to a plane defined by, e.g., the first rear cover 212.

According to an embodiment, the second housing 220 may include a third side 220a and a fourth side 220b. For example, the third side 220a may be provided to face in an upper direction (e.g., +Z-axis direction). The third side 220a may be, e.g., a side (e.g., surface) on which at least a portion of the flexible display 230 is disposed. The third side 220a may refer to, e.g., a virtual side (e.g., surface) overlapping at least a portion of the flexible display 230. The fourth side 220b may be provided to face in a lower direction (e.g., −Z1-axis direction). The fourth side 220b may be, e.g., a side (e.g., surface) on which the second rear cover 222 is disposed. The fourth side 220b may be parallel to the third side 220a. The fourth side 220b may refer to a plane defined by, e.g., the second rear cover 222.

According to an embodiment, when the electronic device 101 is unfolded, the first side 210a and the third side 220a may be positioned within one arbitrary virtual plane (e.g., an XY plane). For example, the first side 210a and the third side 220a forms the same plane when the electronic device 101 is unfolded. For example, the first side 210a and the third side 220a is disposed to form substantially 180 degrees with respect to the XY plane in the unfolded state. When the electronic device 101 is unfolded, the second side 210b and the fourth side 220b may be positioned within another arbitrary virtual plane (e.g., an XY plane). For example, the second side 210b and the fourth side 220b form the same plane in the unfolded state of the electronic device 101. For example, the second side 210b and the fourth side 220b may be disposed to form substantially 180 degrees with respect to the XY plane in the unfolded state.

According to an embodiment, in the folded state of the electronic device 101, at least a portion of the first side 210a and at least a portion of the third side 220a may face each other. For example, in the folded state of the electronic device 101, the angle between the first side 210a and the third side 220a may be zero (0) degrees from the XY plane. As the electronic device 101 is folded from the unfolded state, the angle between the first side 210a and the third side 220a from the XY plane may gradually decrease. For example, the angle formed between the first side 210a and the third side 220a from the XY plane in the intermediate state may be determined between about zero (0) degrees and about 180 degrees. In the folded state of the electronic device 101, the second side 210b and the fourth side 220b may be parallel to each other. For example, the second side 210b and the fourth side 220b face in opposite directions in the folded state of the electronic device 101.

According to an embodiment, the pair of housings 210 and 220 included in the electronic device 101 is not limited to the shape and coupling shown but may rather be implemented in other shapes or via a combination and/or coupling of other components.

According to an embodiment, the first housing 210 may include a first side frame 211. The first side frame 211 may constitute a lateral side (e.g., lateral surface or side surface) of the first housing 210. The first side frame 211 may form part of the exterior of the first housing 210. The first side frame 211 may be provided to protect components received inside the electronic device 101 from the outside.

According to an embodiment, the first side frame 211 may include a first side member 211a, a second side member 211b, and/or a third side member 211c. The first side member 211a may have a first length along a first length direction (e.g., Y-axis direction). The second side member 211b may extend from the first side member 211a in a substantially vertical direction (e.g., the X-axis direction). The second side member 211b may extend to have a second length equal to or different from the first length. The third side member 211c may extend from the second side member 211b in a substantially vertical direction (e.g., the Y-axis direction). The third side member 211c may extend in a direction substantially parallel to the first side member 211a. The third side member 211c may have a first length along the first length direction (e.g., Y-axis direction).

According to an embodiment, the first side member 211a, the second side member 211b, and the third side member 211c may be disposed to be visible from the outside. At least a portion of the first side member 211a, the second side member 211b, and/or the third side member 211c may be formed of a curved side (e.g., surface). The first side frame 211 may be formed in a rectangular (e.g., square or rectangular) shape by the first side member 211a, the second side member 211b, and the third side member 211c. The first side member 211a, the second side member 211b, and the third side member 211c may be integrally formed, but are not limited thereto.

According to an embodiment, the second housing 220 may include a second side frame 221. The second side frame 221 may constitute a lateral side (e.g., lateral surface or side surface) of the second housing 220. The second side frame 221 may form part of the exterior of the second housing 220. The second side frame 221 may be provided to protect components received inside the electronic device 101 from the outside.

According to an embodiment, the second side frame 221 may include a fourth side member 221a, a fifth side member 221b, and/or a sixth side member 221c. The fourth side member 221a may have a third length along a first length direction (e.g., Y-axis direction). The fifth side member 221b may extend from the fourth side member 221a in a substantially vertical direction (e.g., the X-axis direction). The fifth side member 221b may extend to have a fourth length equal to or different from the third length. The sixth side member 221c may extend from the fifth side member 221b in a substantially vertical direction (e.g., the Y-axis direction). The sixth side member 221c may extend in a direction substantially parallel to the fourth side member 221a. The sixth side member 221c may have a third length along the first length direction (e.g., Y-axis direction).

According to an embodiment, the fourth side member 221a, the fifth side member 221b, and the sixth side member 221c may be disposed to be visible from the outside. At least a portion of the fourth side member 221a, the fifth side member 221b, and/or the sixth side member 221c may be formed of a curved side (e.g., surface). The second side frame 221 may be formed in a rectangular (e.g., square or rectangular) shape by the fourth side member 221a, the fifth side member 221b, and the sixth side member 221c. The first length may be substantially equal to the third length. The second length may be substantially equal to the fourth length. The fourth side member 221a, the fifth side member 221b, and the sixth side member 221c may be integrally formed, but are not limited thereto.

According to an embodiment, in the unfolded state of the electronic device 101, the first side member 211a and the fourth side member 221a may be positioned substantially in a straight line. In the unfolded state of the electronic device 101, the second side member 211b and the fifth side member 221b may be parallel to each other. In the unfolded state of the electronic device 101, the third side member 211c and the sixth side member 221c may be positioned substantially in a straight line.

According to an embodiment, in the folded state of the electronic device 101, the first side member 211a and the fourth side member 221a may overlap each other. In the folded state of the electronic device 101, the second side member 211b and the fifth side member 221b may overlap each other. In the folded state of the electronic device 101, the third side member 211c and the sixth side member 221c may overlap each other.

According to an embodiment, the first housing 210 may include a first rear cover 212. The first rear cover 212 may form at least a portion of the second side 210b of the first housing 210. The first rear cover 212 may be combined with the first side frame 211. The first rear cover 212 may be integrally formed with, e.g., the first side frame 211.

According to an embodiment, the second housing 220 may include a second rear cover 222. The second rear cover 222 may form at least a portion of the fourth side 220b of the second housing 220. The second rear cover 222 may be combined with the second side frame 221. The second rear cover 222 may be integrally formed with, e.g., the second side frame 221.

According to an embodiment, the first rear cover 212 and/or the second rear cover 222 may be formed of at least one of laminated or colored glass, ceramic, Glastic, polymer, or metal (e.g., aluminum, stainless steel (STS), or magnesium), or a combination thereof.

According to an embodiment, the electronic device 101 may include a flexible display 230 (e.g., a foldable display or a main display). The flexible display 230 may be disposed across the first housing 210, the hinge 240 and the second housing 220. The flexible display 230 may be disposed from the first side 210a of the first housing 210 across the hinge structure 240 up to at least a portion of the third side 220a of the second housing 220. The flexible display 230 may be disposed so that the first side 210a of the first housing 210 and/or the third side 220a of the second housing 220 overlap. A portion of the flexible display 230 corresponding to the hinge 240 may be bent according to the rotation of the hinge 240.

According to an embodiment, in the unfolded state, the flexible display 230 may be disposed to be visible from the outside. In the folded state, the flexible display 230 may be disposed to be invisible from the outside.

According to an embodiment, the electronic device 101 may further include a sub display 280 (or auxiliary display). The sub display 280 may be disposed to be at least partially exposed to the second side 210b of the first housing 210. The sub display 280 may display state information about the electronic device 101 in the folded state of the electronic device 101. The sub display 280 may be disposed to be viewed from the outside through at least a partial area of the first rear cover 212.

According to an embodiment, the electronic device 101 may include a protective cover 231. The protective cover 231 may be positioned to protect the edges or edge portions of the flexible display 230. The protective cover 231 may form part of the exterior of the electronic device 101.

According to an embodiment, the electronic device 101 may include at least one of an input device (e.g., the microphone 203), a sound output device (e.g., the receiver 201 for phone calls or speaker 202), sensor modules 204, a camera module (the first camera module 205 or second camera module 208), a physical button 206, a connector port 207, a key input device (not shown), or an indicator (not shown), disposed in the first inner space 214 of the first housing 210 or the second inner space 224 of the second housing 220. The electronic device 101 may be configured to omit at least one of the above-described components or add other components.

According to an embodiment, the input device may include a plurality of microphones disposed to detect the direction of sound. The sound output device may include, e.g., the receiver 201 for phone calls and the speaker 202. The sound output devices (i.e., receiver 201 and speaker 202) may be disposed to face the outside through at least one speaker hole formed in the first housing 210 or the second housing 220. The connector port 207 may be disposed to face the outside through a connector port hole formed in the first housing 210 or the second housing 220.

According to an embodiment, the sensor module 204 may generate an electrical signal or a data value corresponding to an internal operating state of the electronic device 101 or an external environmental state. The sensor module 204 may include at least one of a proximity sensor, an illuminance sensor, a time of flight (TOF) sensor, an ultrasonic sensor, a fingerprint recognition sensor, a gesture sensor, a gyro sensor, an air pressure sensor, a magnetic sensor, an accelerometer, a grip sensor, a color sensor, an infrared (IR) sensor, a biometric sensor, a temperature sensor, or a humidity sensor.

According to an embodiment, the camera module may include a first camera module 205 disposed on the front side (e.g., side (e.g., surface) in the +Z-axis direction) of the electronic device 101 or a second camera module 208 disposed on the rear side (e.g., side (e.g., surface) in the −Z-axis direction) of the electronic device 200. The first camera module 205 and/or the second camera module 208 may include one or more lenses, an image sensor, and/or an image signal processor. For example, the first camera module 205 may be disposed under the flexible display 230 and be configured to capture a subject through a portion of the active area of the flexible display 230. The flash 209 may be disposed on the second camera module 208. The flash 209 may include, e.g., a light emitting diode (LED) or a xenon lamp.

According to an embodiment, the electronic device 101 may include an antenna. The antenna may include, e.g., an ultra-wideband (UWB) antenna, a near-field communication (NFC) antenna, a wireless charging antenna, and/or a magnetic secure transmission (MST) antenna. The antenna may perform short-range communication with, e.g., an external device or may wirelessly transmit or receive power necessary for charging.

According to an embodiment, an antenna structure may be formed by a portion of the housing 210 and/or 220 or a combination thereof. For example, the antenna may include a communication antenna at least a portion of which is exposed to the outside and which forms at least a portion of the exterior of the electronic device 101. The communication antenna may be used for communication (e.g., Wi-Fi) with an external electronic device.

In the following detailed description, a configuration in which a pair of housings (or referred to as a ‘housing’) are coupled to be rotatable by a hinge structure is described as an example. However, it should be noted that the electronic device according to various embodiments of the disclosure is not limited thereto. For example, according to various embodiments, the electronic device may include three or more housings. In the embodiment disclosed below, a “pair of housings” may mean two rotatably-coupled housings among three or more housings.

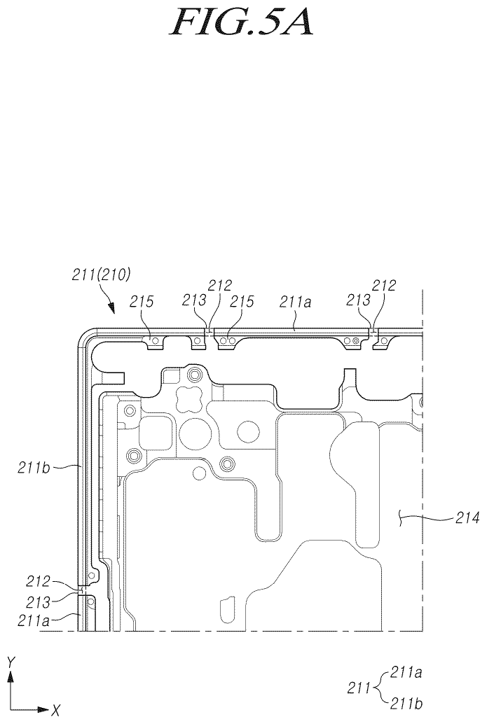

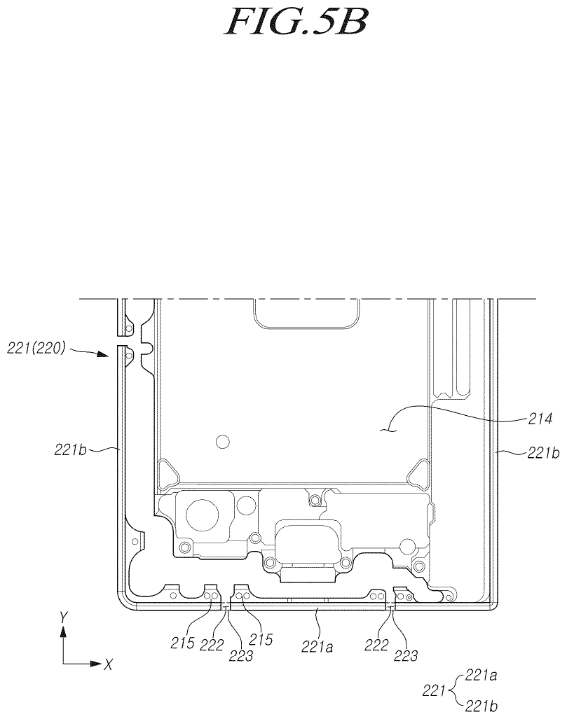

FIG. 5A is a plan view illustrating a first housing according to an embodiment of the disclosure.

FIG. 5B is a plan view illustrating a second housing according to an embodiment of the disclosure.

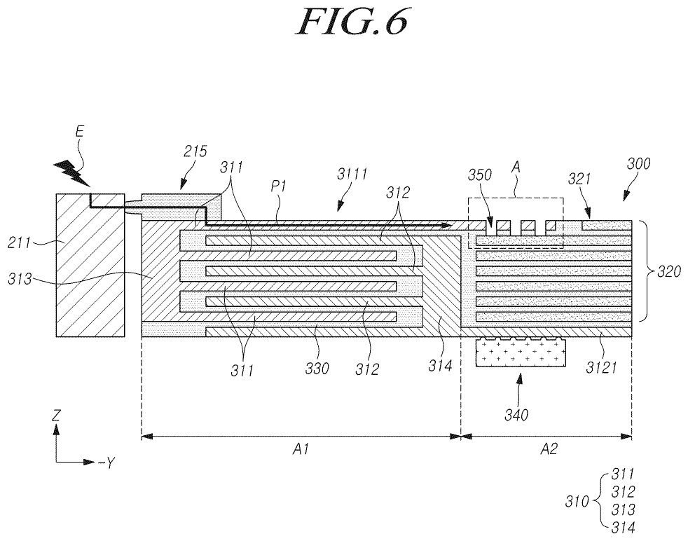

The embodiments of FIGS. 5A and 5B may be selectively combined with the embodiments of FIGS. 1 to 4 and the embodiments of FIGS. 6 to 8, 9A, 9B, 10, and 11.

Referring to FIGS. 5A and 5B, the electronic device 101, according to an embodiment, may include a first housing 210 and a second housing 220 that form the exterior of the electronic device 101.

According to an embodiment, the first housing 210 may include a first side frame 211 constituting a portion of the exterior of the first housing 210. For example, the first side frame 211 may constitute a lateral side (e.g., surface) of the first housing 210.

According to an embodiment, the first side frame 211 may be formed of a conductive material such as a metal material. For example, the first side frame 211 may be formed of a metal material including aluminum (Al) or titanium.

According to an embodiment, as the first side frame 211 is formed of a conductive material, it may function as an antenna (or antenna radiator) of the electronic device 101. The first side frame 211 may transmit or receive a communication signal (e.g., a radio frequency (RF) signal) to or from an external electronic device (e.g., the electronic device 102, the electronic device 104, or the server 108). The first side frame 211 may be electrically connected to a communication module (e.g., the communication module 190 of FIG. 1) of the electronic device 101. For example, the first side frame 211 may be electrically connected to the communication module through an RF line. The RF line may be configured to transfer a radio frequency (RF) signal. For example, the RF line may be configured to transfer the RF signal processed by the communication module of the electronic device 101 to the first side frame 211 serving as an antenna, or to transfer the RF signal received by the first side frame 211 to the communication module.

According to an embodiment, the first side frame 211 may include a plurality of first segmenters 212. The first side frame 211 may be physically divided into the plurality of portions by a plurality of first segmenters 212. The first segmenter 212 may be a space (or a gap) formed in the first side frame 211 so that one first side frame 211 is segmented (e.g., divided) into a plurality of portions. The first segmenter 212 may be a space (or a gap) formed between a plurality of first side frames 211 as the plurality of first side frames 211 are spaced apart from each other.

According to an embodiment, the first side frame 211 may include a 1-1th side frame 211a and a 1-2th side frame 211b physically segmented by the plurality of first segmenters 212. The 1-1th side frame 211a may be a portion of the first side frame 211 disposed between corners of the first housing 210. The 1-2th side frame 211b may be a portion of the first side frame 211 including the corner of the first housing 210.

According to an embodiment, the first side frame 211 may include a plurality of first insulating members 213 disposed on a plurality of first segmenters 212 corresponding thereto. The first side frame 211 may be electrically segmented by the first insulating member 213. The first insulating member 213 may include a material having low conductivity or a material having low permittivity. If the first side frame 211 is used as an antenna for the electronic device 101, the resonant frequency of the antenna may be determined according to the physical length of the first side frame 211. It may be segmented into the plurality of portions (e.g., the 1-1th side frame 211a and the 1-2th side frame 211b) having different lengths by the first insulating member 213 disposed in the first segmenter 212 of the first side frame 211. The segmented frames (e.g., the 1-1th side frame 211a and the 1-2th side frame 211b) may have different resonant frequencies. The electronic device 101 may perform communication in various frequency bands (e.g., short-range communication or long-range communication) through segmented frames having different resonant frequencies (e.g., 1-1th side frame 211a and 1-2th side frame 211b).

According to an embodiment, the first side frame 211 may be electrically connected to an electronic component (e.g., the communication module 190 of FIG. 1 or the printed circuit board 300 of FIG. 6) disposed in the housings 210 and 220 through a conductive member 215. For example, the conductive member 215 may include at least one of C-clip, conductive foam, conductive gasket, or conductive tape.

According to an embodiment, the second housing 220 may include a second side frame 221 forming a portion of the exterior of the second housing 220. For example, the second side frame 221 may constitute a lateral side (e.g., surface) of the second housing 220.

According to an embodiment, the second side frame 221 of the second housing 220 may be wholly or partially identical in shape, structure, and/or function to the first side frame 211 of the first housing 210. For example, the second side frame 221 may be used as an antenna (or antenna radiator) like the first side frame 211.

According to an embodiment, the second side frame 221 may include a 2-1 th side frame 221a and a 2-2th side frame 221b physically segmented (e.g., divided) by a plurality of second segmenters 222. According to an embodiment, the second side frame 221 may include a plurality of second insulating members 223 disposed on the plurality of second segmenters 222 corresponding thereto. According to an embodiment, the second side frame 221 may be electrically connected to an electronic component (e.g., the communication module 190 of FIG. 1 or the printed circuit board 300 of FIG. 6) disposed in the housing 210 and 220 through a conductive member 215.

According to an embodiment, the side frames 211 and 221 may be electrically connected to at least one printed circuit board (e.g., the printed circuit board 300 of FIG. 6). The printed circuit board may be electrically connected to the ground or may include the ground. Charges accumulated in the electronic device 101 may be conducted to the side frames 211 and 221 to move to a ground having a relatively low potential through the printed circuit board. Here, the accumulated charges may refer to charges generated by the operation of an electronic component disposed inside the electronic device 101. Alternatively, the accumulated charges may refer to charges accumulated outside (or on the side (e.g., surface)) of the electronic device 101 and conducted into the electronic device 101 through a gap formed in the electronic device 101. Hereinafter, the accumulated charges may encompass the above-described charges.

According to an embodiment, an electrostatic discharge (ESD) phenomenon may occur in the electronic device 101 due to the accumulated charges. The ESD phenomenon may refer to an electrical phenomenon caused by instantaneous movement of charges (or static electricity) accumulated in one portion of the electronic device 101 to another portion of the electronic device 101 due to various factors.

According to an embodiment, the charges accumulated in the electronic device 101 may move into the electronic device 101 through a gap formed by the design of the electronic device 101. If a ground structure (or ESD path) for discharging charges accumulated in the electronic device 101 is not designed (or provided), the accumulated charges may be discharged to an electronic component (e.g., the communication module 190 of FIG. 1) disposed inside the electronic device 101 to damage the electronic component.

In general, an electronic device may include an inductor (or shunt inductor) connected in parallel with the electronic component or antenna (e.g., first side frame 211 or second side frame 221) to discharge the accumulated charges.

The inductor may be electrically connected to the ground to form an ESD path through which accumulated charges move. By including the inductor, the electronic device may secure an ESD path for controlling the ESD introduced from a metal housing (e.g., the first side frame 211, the second side frame 221, or the conductive member 215).

However, if the frequency band is a predetermined section (e.g., 4 GHz) or more, the inductor connected to the antenna may operate like a capacitor due to a self-resonant frequency (SRF), thereby reducing the antenna's performance.

Various embodiments of the disclosure may provide a path (e.g., an ESD path) through which accumulated charges move without the presence of an inductor.

Hereinafter, an electronic device 101 including an ESD path is described with reference to FIGS. 6 to 8, 9A, 9B, 10, and 11.

FIG. 6 is a cross-sectional view illustrating an electronic device in an ESD path according to an embodiment of the disclosure.

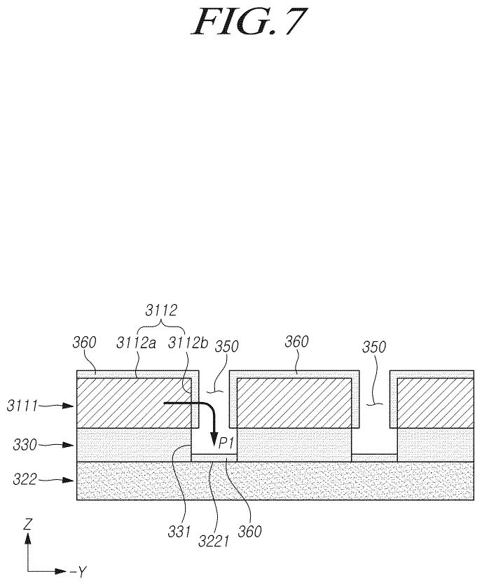

FIG. 7 is an enlarged view of portion A of FIG. 6 according to an embodiment of the disclosure.

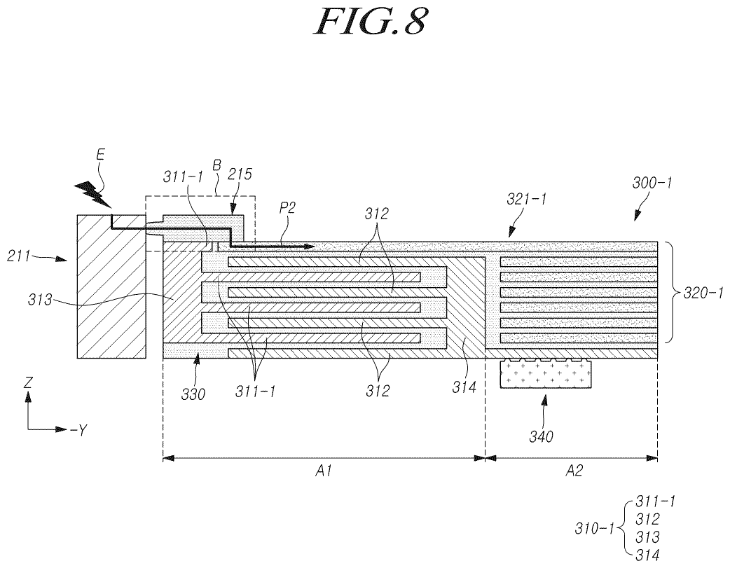

The embodiments of FIGS. 6 and 7 may be selectively combined with the embodiments of FIGS. 1 to 4, 5A, and 5B and the embodiments of FIGS. 8, 9A, 9B, 10, and 11.

The printed circuit board 300 of FIGS. 6 and 7 are described based on a case where it is connected to the first side frame 211 of the first housing (e.g., the first housing 210 of FIG. 4), but the same description may also apply where the printed circuit board 300 is connected to the second side frame 221 of the second housing (e.g., the second housing 220).

Referring to FIGS. 6 and 7, the electronic device 101, according to an embodiment may include a printed circuit board (PCB) 300 electrically connected to the side frame (e.g., the first side frame 211) of the housing (e.g., the first housing 210 of FIG. 5A).

According to an embodiment, the printed circuit board 300 may include at least one of a conductive member 215, a signal layer 310, a ground layer 320, an insulation layer 330, an electronic component 340, (e.g., the communication module 190 of FIG. 1), a discharge hole 350, or a coating layer 360.

According to an embodiment, the conductive member 215 may be disposed on the printed circuit board 300. For example, the conductive member 215 may be disposed on the first side (e.g., one side (e.g., surface) facing in the +Z axis direction) of the printed circuit board 300. The conductive member 215 may be attached to the side (e.g., surface) of the printed circuit board 300 through soldering. The conductive member 215 may be electrically connected to the signal layer 310 of the printed circuit board 300. For example, the conductive member 215 may be connected to the first conductive layer (or the uppermost signal layer, the first signal layer) 3111 disposed at the uppermost end among the plurality of first conductive layers 311 of the signal layer 310. The electronic device 101 may transfer an electrical signal (e.g., static electricity or communication signal) from the side frame (e.g., the first side frame 211) to the printed circuit board 300 through the conductive member 215.

According to an embodiment, the signal layer 310 may be provided to transmit electrical signal(s) (e.g., static electricity or communication signal) to the electronic component 340 or the ground layer 320.

According to an embodiment, the signal layer 310 may include a plurality of conductive layers 311 and 312. For example, the conductive layer of the signal layer 310 may have a copper foil shape.

According to an embodiment, the signal layer 310 may include a plurality of first conductive layers 311 and a plurality of second conductive layers 312 alternately disposed in the vertical direction (or the upper/lower direction) (e.g., the ±Z axis direction). The plurality of first conductive layers 311 and the plurality of second conductive layers 312 may be disposed to be spaced apart from each other in the vertical direction.

According to an embodiment, the plurality of first conductive layers 311 are odd-numbered layers (first, third, fifth, seventh layers . . . ) of the signal layer 310 sequentially arranged from an upper side (e.g., +Z-axis direction) to a lower side (e.g., −Z-axis direction) of the printed circuit board 300). The plurality of first conductive layers 311 may be referred to as odd-numbered conductive layer groups. The plurality of first conductive layers 311 may be connected to each other through a first connection portion 313.

According to an embodiment, the first conductive layer (or the uppermost signal layer) 3111 disposed at the uppermost end among the plurality of first conductive layers 311 may be disposed on the capacitor area A1 and the ground area A2 to be described below. For example, the uppermost signal layer 3111 may extend in the horizontal direction (e.g., ±Y-axis direction) to span the capacitor area A1 and the ground area A2. The length of the uppermost signal layer 3111 may be designed to be longer (or greater) than the length of the remaining layers of the signal layer 310. The length of the uppermost signal layer 3111 may be designed to be longer (or greater) than the length of the layer (or the uppermost ground layer) 321 disposed at the uppermost end among the plurality of layers of the ground layer 320.

According to an embodiment, the plurality of second conductive layers 312 are even-numbered layers (second, fourth, sixth, eighth layers . . . ) of the signal layer 310 sequentially arranged from an upper side (e.g., +Z-axis direction) to a lower side (e.g., −Z-axis direction) of the printed circuit board 300). The plurality of second conductive layers 312 may be referred to as even-numbered conductive layer groups. The plurality of second conductive layers 312 may be connected to each other through a second connection portion 314.

According to an embodiment, the signal layer 310 may function as a capacitor by being separated into the plurality of first conductive layers 311 and the plurality of second conductive layers 312. An area including the signal layer 310 in the printed circuit board 300 may be referred to as a capacitor area A1.

According to an embodiment, the ground layer 320 may be provided to ground the electronic device 101. The ground layer 320 may be electrically connected to the ground area (not shown) of the electronic device 101 or may form a separate ground area A2.

According to an embodiment, the ground layer 320 may include a plurality of conductive layers. For example, the conductive layer of the ground layer 320 may have a copper foil shape. The plurality of conductive layers of the ground layer 320 may be spaced apart from each other in the vertical direction (or upper/lower direction) (e.g., a ±Z-axis direction). An area including the ground layer 320 in the printed circuit board 300 may be referred to as a ground area A2. For example, the ground area A2 may include a ground layer 320 formed of a single layer communicating with the discharge hole 350.

According to an embodiment, the signal layer 310 and the ground layer 320 may be spaced apart from each other in the horizontal direction (e.g., the ±Y-axis direction).

According to an embodiment, the insulation layer 330 may fill a space between the signal layer 310 and the ground layer 320. For example, the insulation layer 330 may be disposed between the plurality of conductive layers (e.g., the plurality of conductive layers 311 and 312) of the signal layer 310 or may surround the plurality of conductive layers of the signal layer 310. For example, the insulation layer 330 may be disposed between the plurality of conductive layers of the ground layer 320 or may surround the plurality of conductive layers of the ground layer 320. At least a portion of the insulation layer 330 may be exposed to the outside to form the exterior of the printed circuit board 300. For example, the insulation layer 330 may include FR-4, Teflon, epoxy, aluminum, glass fiber, or ceramic.

According to an embodiment, the electronic component 340 may be disposed on the printed circuit board 300. For example, the electronic component 340 may be disposed on a second side (e.g., one side (e.g., surface) facing in the −Z axis direction) opposite the first side (e.g., surface) of the printed circuit board 300. The electronic component 340 may be electrically connected to the signal layer 310 of the printed circuit board 300. For example, the electronic component 340 may be connected to the second conductive layer (or the lowermost signal layer) 3121 disposed at the lowermost end among the plurality of second conductive layers 312 of the signal layer 310 of the printed circuit board 300.

According to an embodiment, the discharge hole 350 may be provided to discharge charges (or static electricity) E accumulated in the electronic device 101. At least one discharge hole 350 may be provided. The discharge hole 350 may be recessed to a predetermined depth from the side (e.g., the first side (e.g., surface)) of the printed circuit board 300 in the vertical direction (or, upper/lower direction) (e.g., ±Z-axis direction). For example, the discharge hole 350 may be recessed from the first conductive layer (or uppermost signal layer) 3111 disposed at the uppermost end among the plurality of first conductive layers 311 of the signal layer 310 to the second ground layer (or exposed ground layer) 322 among the plurality of layers of the ground layer 320. The second ground layer 322 of the ground layer 320 may be visually recognized (or exposed) from the outside by the discharge hole 350. The discharge hole 350 may be defined by a surface layer 3112 of the first conductive layer 3111, a surface 331 of the insulation layer 330, and an upper surface 3221 of the ground layer 320 (e.g., the second ground layer 322).

According to an embodiment, the discharge hole 350 may induce discharge of accumulated charges (or static electricity) E of the electronic device 101 from the signal layer 310 to the ground layer 320. For example, the charged charge of the electronic device 101 may be discharged between the signal layer (e.g., uppermost signal layer 3111) and the ground layer (e.g., exposed ground layer 322) spaced apart in the vertical direction through the space occupied by the discharge hole 350. The electronic device 101 may include the ESD path P1 constituted of the side frame (e.g., the first side frame 211), the conductive member 215, the signal layer (e.g., the uppermost signal layer 3111), and the exposed ground layer (e.g., the second ground layer 322) through the discharge hole 350.

According to an embodiment, a plurality of discharge holes 350 may be provided. If the number of discharge holes 350 provided in the printed circuit board 300 increases, the movement of charges through the discharge hole 350 increases, enhancing the discharge effect.

According to an embodiment, the coating layer 360 may cover at least a portion of the side (e.g., surface) of the printed circuit board 300. The coating layer 360 may be provided to prevent corrosion of the layer of the printed circuit board 300 exposed to the outside. For example, the coating layer 360 may be gold plating, but the disclosure is not limited thereto. The coating layer 360 may cover the surface layer 3112 of the signal layer 310 exposed to the outside. For example, the coating layer 360 may cover the upper surface layer 3112a and the side surface layer 3112b of the uppermost signal layer 3111 of the signal layer 310. The coating layer 360 may cover the upper surface 3221 of the ground layer 320 exposed to the outside. For example, the coating layer 360 may cover the upper surface 3221 of the second ground layer 322 of the ground layer 320 exposed to the outside. On the other hand, the coating layer 360 may not be provided on the surface 331 of the insulation layer 330 exposed to the outside for electrostatic discharge (ESD).

FIG. 8 is a cross-sectional view illustrating an electronic device in an ESD path according to an embodiment of the disclosure.

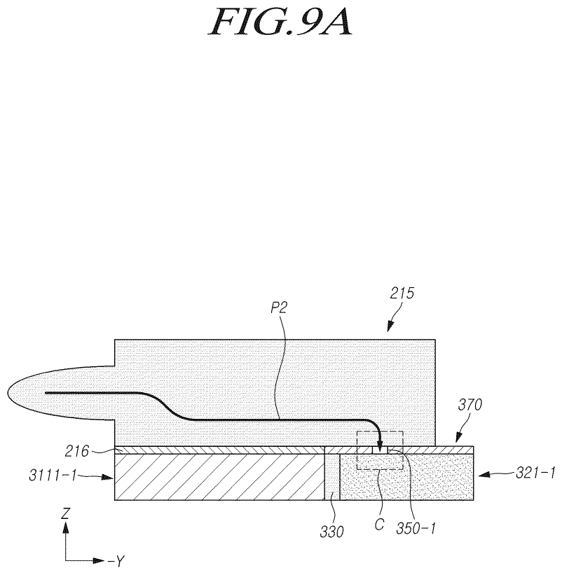

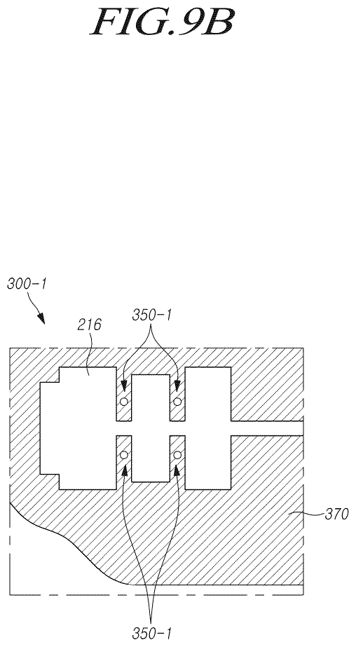

FIG. 9A is an enlarged view of portion B of FIG. 8 according to an embodiment of the disclosure.

FIG. 9B is a plan view illustrating a printed circuit board with portion C of FIG. 9A enlarged and viewed from above according to an embodiment of the disclosure.

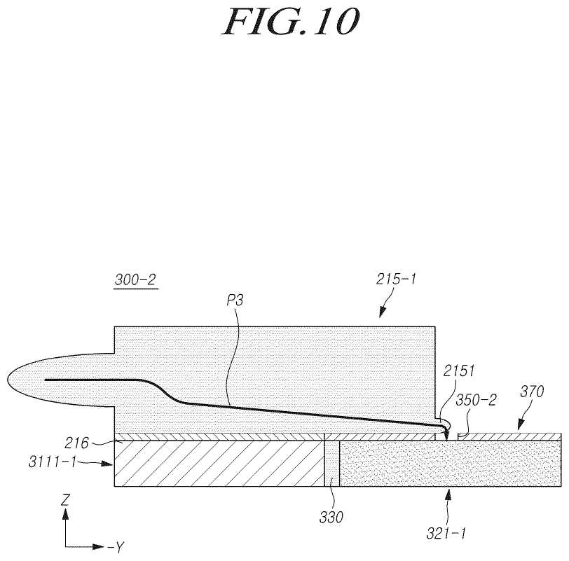

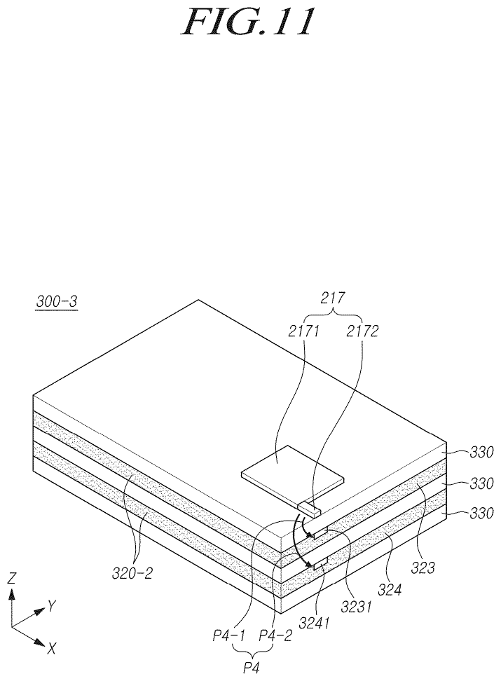

The embodiments of FIGS. 8, 9A, and 9B may be selectively combined with the embodiments of FIGS. 1 to 4, 5A, 5B, 6, and 7, and the embodiments of FIGS. 10 and 11.

The printed circuit board 300-1 of FIGS. 8 and 9B may be identical in whole or part to the printed circuit board 300 of FIGS. 6 and 7.

Referring to FIGS. 8, 9A, and 9B, the printed circuit board 300-1 according to an embodiment may include at least one of a conductive member 215, a signal layer 310-1, a ground layer 320-1, an insulation layer 330, an electronic component 340, or a protective layer 370.

According to an embodiment, the first conductive layer (or the uppermost signal layer) 3111-1 disposed at the uppermost end among the plurality of first conductive layers 311-1 of the signal layer 310-1 may overlap the conductive member 215. For example, the uppermost signal layer 3111-1 may be covered by the conductive member 215 when the printed circuit board 300-1 is viewed from above (e.g., +Z axis direction). The length of the uppermost signal layer 3111-1 may be designed to be shorter (e.g., less) than the length of the remaining layers of the signal layer 310-1.

According to an embodiment, the layer (or the uppermost ground layer) 321-1 disposed at the uppermost end among the plurality of layers of the ground layer 320-1 may be disposed on the capacitor area A1 and the ground area A2. For example, the uppermost ground layer 321-1 may extend in the horizontal direction (e.g., ±Y-axis direction) to span the capacitor area A1 and the ground area A2. The length of the uppermost ground layer 321-1 may be designed to be longer (e.g., greater) than the length of the remaining layers of the ground layer 320-1. The length of the uppermost ground layer 321-1 may be designed to be longer (e.g., greater) than the length of the uppermost signal layer 3111-1 of the signal layer 310-1.

According to an embodiment, the conductive member 215 may be attached (or soldered) onto the printed circuit board 300-1 through a solder member 216.

According to an embodiment, the protective layer 370 may form at least a portion of the side (e.g., surface) of the printed circuit board 300-1. The protective layer 370 may be coated (e.g., polymer coated) on the side (e.g., surface) of the printed circuit board 300-1 to protect the printed circuit board 300-1 from the outside. For example, the protective layer 370 may reduce physical damage to the printed circuit board 300-1 due to scratches or friction or chemical damage such as corrosion due to external environment. For example, the protective layer 370 may include a solder resist or a solder mask. As shown in FIG. 9A, the protective layer 370 may be disposed to span on the insulation layer 330 and/or the ground layer 320-1.

According to an embodiment, the protective layer 370 may include a discharge hole 350-1 penetrating the protective layer 370. The discharge hole 350-1 may be recessed to a predetermined depth in the vertical direction (or upper/lower direction) (e.g., the ±Z axis direction) (e.g., the ±Z axis direction) from the side (e.g., surface) (e.g., the protective layer 370) of the printed circuit board 300-1. For example, the discharge hole 350-1 may be recessed from the protective layer 370 to the uppermost ground layer 321-1 among the plurality of layers of the ground layer 320-1. The upper side of at least a portion of the uppermost ground layer 321-1 of the ground layer 320-1 may be opened by the discharge hole 350-1.

According to an embodiment, the discharge hole 350-1 may be positioned under the conductive member 215. The discharge hole 350-1 may be disposed between the conductive member 215 and the uppermost ground layer 321-1 of the ground layer 320-1. The discharge hole 350-1 may be defined by a lower side (e.g., one side (e.g., surface) facing in the −Z axis direction) of the conductive member 215, one side (e.g., surface) of the protective layer 370, and an upper (e.g., one side (e.g., surface) facing in the +Z axis direction) of the uppermost ground layer 321-1 of the ground layer 320-1.

According to an embodiment, a plurality of discharge holes 350-1 may be provided. As illustrated in FIG. 9B, the plurality of discharge holes 350-1 may be positioned in an area occupied by the protective layer 370 of the side (e.g., surface) of the printed circuit board 300-1. For example, the plurality of discharge holes 350-1 may be disposed between the solder members (e.g., solder pads) 216 on the area occupied by the protective layer 370.

According to an embodiment, the discharge hole 350-1 may be provided to discharge charges (or static electricity) E accumulated in the electronic device 101. The discharge hole 350-1 may induce discharge of accumulated charges (or static electricity) E of the electronic device 101 from the conductive member 215 to the ground layer 320-1. For example, the accumulated charges of the electronic device 101 may be discharged between the conductive member 215 and the ground layer (e.g., the uppermost ground layer 321-1) spaced apart vertically through the space occupied by the discharge hole 350-1. The electronic device 101 may include an ESD path P2 constituted of the side frame (e.g., the first side frame 211), the conductive member 215, and the ground layer (e.g., the uppermost ground layer 321-1) through the discharge hole 350-1.

According to an embodiment, the thickness of the protective layer 370 may be smaller (e.g., less) than that of the insulation layer 330. For example, the thickness of the protective layer 370 may be about 20 μm, and the thickness of the insulation layer 330 may be about 30 μm. In this case, as illustrated in FIGS. 9A and 9B, the vertical separation distance between the conductive member 215 and the ground layer 320 is shorter than the vertical separation distance between the first signal layer 310 and the ground layer 320, thereby smoothing discharging of static electricity.

FIG. 10 is a schematically view illustrating an electronic device in an ESD path according to an embodiment of the disclosure.

The embodiments of FIG. 10 may be selectively combined with the embodiments of FIGS. 1 to 4, 5A, 5B, 6 to 8, 9A, and 9B and the embodiments of FIG. 11.

The printed circuit board 300-2 of FIG. 10 may be identical in whole or part to the printed circuit boards 300 and 300-1 of FIGS. 6 to 8, 9A, and 9B.

Referring to FIG. 10, a printed circuit board 300-2 according to an embodiment may include at least one of a conductive member 215-1, a signal layer (e.g., the signal layer 310-1 of FIG. 8), a ground layer (e.g., the ground layer 320-1 of FIG. 8), an insulation layer 330, an electronic component (e.g., the electronic component 340 of FIG. 8), or a protective layer 370.

According to an embodiment, the conductive member 215-1 may include a discharge protrusion 2151 protruding toward the discharge hole 350-2. The discharge protrusion 2151 may protrude from one side (e.g., one side (e.g., surface) facing in the −Y-axis direction) of the conductive member 215-1. The discharge protrusion 2151 may be disposed on the discharge hole 350-2 (e.g., in the +Z axis direction).

According to an embodiment, the protective layer 370 may include a discharge hole 350-2 penetrating the protective layer 370. The discharge hole 350-2 may be recessed to a predetermined depth from the side (or surface) (e.g., the protective layer 370) of the printed circuit board 300-2 in the vertical direction (or upper/lower direction) (e.g., the ±Z axis direction). For example, the discharge hole 350-2 may be recessed from the protective layer 370 to the uppermost ground layer 321-1 of the ground layer 320-1. The uppermost layer 321-1 of the ground layer 320-1 may be visually recognized (or exposed) from the outside by the discharge hole 350-2.

According to an embodiment, the discharge hole 350-2 may be disposed under the discharge protrusion 2151 (e.g., in the −Z axis direction) of the conductive member 215-1. The discharge hole 350-2 may be disposed between the discharge protrusion 2151 of the conductive member 215-1 and the uppermost ground layer 321-1 of the ground layer 320-1. The discharge hole 350-2 may be defined by one side (e.g., surface) of the protective layer 370 and the upper side (e.g., surface) of the uppermost ground layer 321-1 of the ground layer 320-1. Although not specified in the drawings, a coating layer (e.g., coating layer 360 in FIG. 7) for preventing corrosion may be provided on the upper side (e.g., surface) of the uppermost ground layer 321-1.

According to an embodiment, the discharge hole 350-2 of FIG. 10 may be disposed farther in the horizontal direction (e.g., ±Y-axis direction) from a side frame (e.g., the first side frame 211 of FIG. 8) than the discharge hole 350-1 of FIGS. 9A and 9B.

According to an embodiment, the discharge hole 350-2 may be provided to discharge charges (or static electricity) E accumulated in the electronic device 101. The discharge hole 350-2 may induce discharge of accumulated charges (or static electricity) E of the electronic device 101 from the conductive member 215-1 to the ground layer 320-1. For example, the accumulated charges of the electronic device 101 may be discharged between the discharge protrusion 2151 and the ground layer (e.g., the uppermost ground layer 321-1) of the conductive member 215-1 spaced apart in the vertical direction through the space occupied by the discharge hole 350-2. The electronic device 101 may include an ESD path P3 constituted of the side frame (e.g., the first side frame 211), the conductive member 215-1, and the ground layer (e.g., the uppermost ground layer 321-1) through the discharge hole 350-2.

FIG. 11 is a view schematically illustrating a printed circuit board according to an embodiment of the disclosure.

The embodiment of FIG. 11 may be selectively combined with the embodiments of FIGS. 1 to 4, 5A, 5B, 6 to 8, 9A, 9B, and 10.

The printed circuit board 300-3 of FIG. 11 may be identical in whole or part to the printed circuit boards 300, 300-1, and 300-2 of FIGS. 6 to 8, 9A, 9B, and 10.

Referring to FIG. 11, a printed circuit board 300-3 according to an embodiment may include at least one of a conductive pad 217, a signal layer (e.g., the signal layer 310 of FIG. 6), a ground layer 320-2, an insulation layer 330, an electronic component (e.g., the electronic component 340 of FIG. 6), or a protective layer (e.g., the protective layer 370 of FIGS. 9A and 9B).

According to an embodiment, the conductive pad 217 may be mounted on a side (e.g., surface) of the printed circuit board 300-3. Although not specified in the drawings, the conductive pad 217 may be electrically connected to the above-described conductive member (e.g., the conductive member 215 of FIG. 6). For example, the conductive pad 217 and the conductive member 215 may be electrically connected to each other by physically contacting each other. For example, the conductive member 215 may contact at least a portion (e.g., the body portion 2171 or the extension portion 2172) of the conductive pad. The conductive pad 217 may be electrically connected to the signal layer 310 of the printed circuit board 300-3 by soldering.

According to an embodiment, the conductive pad 217 may include a body portion 2171 and an extension 2172 extending from the body portion 2171 to the edge of the printed circuit board 300-3. The end (or free end) of the extension 2172 of the conductive pad 217 may be disposed on the same plane (e.g., one side (e.g., surface) of the printed circuit board 300-3 parallel to the Y-Z plane) as the discharge portions 3231 and 3241 of the ground layer 320-2 to be described below.

According to an embodiment, the ground layer 320-2 may include a plurality of conductive layers. The ground layer 320-2 may include a first ground layer 323 disposed at the uppermost end among the plurality of conductive layers, and a second ground layer 324 spaced apart from the first ground layer 323 in the vertical direction (or upper/lower direction) (e.g., ±Z-axis direction) through the insulation layer 330. At least one ground layer 323 and 324 of the plurality of conductive layers of the ground layer 320-2 may include discharge portions 3231 and 3241 that are visually recognized (or exposed) at the edge of the printed circuit board 300-3. For example, the first ground layer 323 of the ground layer 320-2 may include a first discharge portion 3231 that is disposed on the same plane (e.g., Y-Z plane) as one side (e.g., surface) of the printed circuit board 300-3 and visually (or exposed) to the outside. For example, the second ground layer 324 of the ground layer 320-2 may include a second discharge portion 3241 that is disposed on the same plane (e.g., Y-Z plane) as one side (e.g., surface) of the printed circuit board 300-3 and visually (or exposed) to the outside.

According to an embodiment, the discharge portions 3231 and 3241 of the ground layer 320-2 may induce discharge of charges (or static electricity) accumulated in the electronic device 101. For example, the accumulated charges of the electronic device 101 may be discharged from the end of the extension 2172 of the conductive pad 217, between the discharge portions 3231 and 3241 of the ground layer 320-2 spaced apart in the vertical direction (or upper/lower direction) (e.g., the ±Z axis direction) on one side (e.g., surface) of the printed circuit board 300-3. The electronic device 101 may include an ESD path P4 constituted of the side frame (e.g., the first side frame 211), the conductive member 215, the conductive pad 217, and the ground layer 320-2 through the discharge portions 3231 and 3241 that are visually recognized (or exposed) to the outside. The ESD path P4 may include a first discharge path P4-1 formed between the extension 2172 of the conductive pad 217 and the first discharge portion 3231 of the first ground layer 323, and a second discharge path P4-2 formed between the extension 2172 of the conductive pad 217 and the second discharge portion 3241 of the second ground layer 324. As the first discharge path P4-1 is provided to be shorter than the second discharge path P4-2, the electrostatic discharge may occur more smoothly in the first discharge path P4-1 than in the second discharge path P4-2.

Various embodiments of the printed circuit boards 300, 300-1, 300-2, and 300-3 according to the disclosure have been described based on the in-folding foldable type electronic device 101, but the disclosure is not limited thereto. For example, the printed circuit boards 300, 300-1, 300-2, and 300-3, according to the disclosure, may be applied in substantially the same manner to out-folding foldable electronic devices that are rotatable in the direction opposite to that of in-folding, and multi-folding foldable electronic devices capable of in-folding and out-folding. Furthermore, the printed circuit boards 300, 300-1, 300-2, and 300-3 according to the disclosure may be applied in substantially the same manner even when the single housing functions as an antenna radiator in an electronic device having a single housing (e.g., a bar-type electronic device).

An electronic device 101, according to an embodiment of the disclosure, may comprise a first housing 210 including a conductive first side frame 211, a second housing 220 including a conductive second side frame 221, a flexible display 230 disposed on the first housing 210 and the second housing 220, a hinge module 240 rotatably coupled between the first housing 210 and the second housing 220, and a printed circuit board (PCB) 300, 300-1, 300-2 disposed on the first housing 210 or the second housing 220, the PCB 300, 300-1, 300-2 including a conductive member 215 electrically connected to the first side frame 211 or the second side frame 221, a signal layer 310, a ground layer 320, and an insulation layer 330. The PCB 300, 300-1, 300-2 may include at least one discharge hole 350, 350-1, 350-2 recessed from a side (e.g., surface) of the PCB 300, 300-1, 300-2 so that the ground layer 320 is visible from the outside and forming a gap between any one of the signal layer 310 or the conductive member 215 and the ground layer 320.

According to an embodiment, the PCB 300, 300-1, 300-2 may include a capacitor area A1 where the signal layer 310, 310-1 is disposed, and a ground area A2 where the ground layer 320, 320-1 is disposed.

According to an embodiment, the signal layer 310 may include a plurality of first conductive layers 311 and a plurality of second conductive layers 312 alternately arranged in a first direction with the plurality of first conductive layers 311. The plurality of first conductive layers 311 may include a first signal layer 3111 disposed at the top of the plurality of first conductive layers 311 and extending across the capacitor area A1 and the ground area A2 in a second direction perpendicular to the first direction.

According to an embodiment, the ground layer 320 may include a plurality of conductive layers. The plurality of conductive layers of the ground layer 320 may include a first ground layer 321 disposed at the top of the plurality of conductive layers, and a second ground layer 322 disposed below the first signal layer 3111 and overlapping at least a portion of the first signal layer 3111. The at least one discharge hole 350 may extend in the first direction from the first signal layer 3111 to the second ground layer 322.

According to an embodiment, the at least one discharge hole 350 may be a space surrounded by the first signal layer 3111, the insulation layer 330, and the second ground layer 322.

According to an embodiment, a length of the first signal layer 3111 in the second direction may be longer than a length of the first ground layer 321 in the second direction.

According to an embodiment, the printed circuit board 300, 300-1, 300-2 may include a coating layer 360 of a conductive material covering an externally exposed side (e.g., surface) of the first signal layer 3111 and a side (e.g., surface) of the second ground layer 322.

According to an embodiment, the electronic device 101 may comprise a discharge path P1 composed of the first side frame 211 or the second side frame 221, the conductive member 215, the first signal layer 3111, and the second ground layer 322. The charge accumulated in the electronic device 101 may move along the discharge path P1 through the at least one discharge hole 350.

According to an embodiment, the ground layer 320-1 may include a plurality of conductive layers. The plurality of conductive layers of the ground layer 320-1 may include a first ground layer 321-1 disposed at the top of the plurality of conductive layers and extending across the capacitor area A1 and the ground area A2 in a second direction perpendicular to the first direction.

According to an embodiment, the PCB 300-1, 300-2 may include a protective layer 370 made of an insulating material disposed on the first ground layer 321-1 of the ground layer 320-1. The at least one discharge hole 350-1, 350-2 may extend in the first direction from the protective layer 370 to the first ground layer 321-1.

According to an embodiment, the at least one discharge hole 350-1 and 350-2 may be a space surrounded by at least a portion of the conductive members 215 and 215-1, the protective layer 370, and the first ground layer 321-1.

According to an embodiment, the signal layer 310-1 may include a plurality of first conductive layers 311-1 and a plurality of second conductive layers 312 alternately arranged in a first direction with the plurality of first conductive layers 311-1. The plurality of first conductive layers 311-1 may include a first signal layer 3111-1 disposed at the top of the plurality of first conductive layers 311. According to an embodiment, a length of the first ground layer 321-1 in the second direction may be longer than a length of the first signal layer 3111-1 in the second direction.

According to an embodiment, the at least one discharge hole 350-1, 350-2 may be disposed below at least a portion of the conductive member 215, 215-1.

According to an embodiment, the conductive member 215-2 may include a discharge protrusion 2151 that protrudes from a side of the conductive member 215-2 and is located above the at least one discharge hole 350-2.

According to an embodiment, the electronic device 101 may comprise a discharge path P2, P3 composed of the first side frame 211 or the second side frame 221, the conductive members 215, 215-1, and the first ground layer 321-1. The charge accumulated in the electronic device 101 may move along the discharge path P2, P3 through the at least one discharge hole 350-1, 350-2.

An electronic device 101, according to an embodiment of the disclosure, may comprise a first housing 210 including a conductive first side frame 211, a second housing 220 including a conductive second side frame 221, a flexible display 230 disposed on the first housing 210 and the second housing 220, a hinge module 240 rotatably coupled between the first housing 210 and the second housing 220, and a printed circuit board 300-3 disposed on the first housing 210 or the second housing 220, and including a conductive pad 217 electrically connected to the first side frame 211 or the second side frame 221, a signal layer 310, a ground layer 320-2, and an insulation layer 330. The ground layer 320-2 may include a plurality of conductive layers. At least one of the plurality of conductive layers may include a discharge portion 3231, 3241 disposed on a same plane as a side (e.g., surface) of the printed circuit board 300-3 to be visible from an outside.

According to an embodiment, the conductive pad 217 may include a body portion 2171 and an extension 2172 extending from the body portion 2171 to an edge of the printed circuit board 300-3.

According to an embodiment, the discharge portion 3231, 3241 may be spaced apart from an end portion of the conductive pad 217 on a side (e.g., surface) of the printed circuit board 300-3.

According to an embodiment, the electronic device 101 may comprise a discharge path P4 constituted of the first side frame 211 or the second side frame 221, the conductive pad 217, and the ground layer 320-2. Charge accumulated in the electronic device 101 may be discharged between the discharge portion 3231, 3241 and the extension of the conductive pad 217.

According to an embodiment, the ground layer 320-2 may include a first ground layer 323 and a second ground layer 324. Each of the first ground layer 323 and the second ground layer 324 may include the discharge portion 3231, 3241 disposed on a same plane as one side surface of the printed circuit board 300-3.

An electronic device, according to an embodiment of the disclosure, may comprise a housing including a conductive side frame, and a printed circuit board 300, 300-1, 300-2 disposed on the housing, and including a conductive member 215 electrically connected to the side frame, a signal layer 310, 310-1, a ground layer 320, 320-1, and an insulation layer 330. The printed circuit board may include at least one discharge hole recessed from a side (e.g., surface) of the printed circuit board so that the ground layer is visible from the outside and forming a gap between any one of the signal layer or the conductive member and the ground layer.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a first housing including a conductive first side frame;
a second housing including a conductive second side frame;
a flexible display disposed on the first housing and the second housing;
a hinge module rotatably coupled between the first housing and the second housing; and
a printed circuit board (PCB) disposed on the first housing or the second housing, the PCB including a conductive member electrically connected to the conductive first side frame or the conductive second side frame, a signal layer, a ground layer, and an insulation layer,
wherein the PCB includes:
at least one discharge hole recessed from a surface of the PCB so that the ground layer is visible from an outside and forming a gap between the signal layer or the conductive member and the ground layer.

2. The electronic device of claim 1, wherein the PCB further includes:
a capacitor area where the signal layer is disposed, and a ground area where the ground layer is disposed.

3. The electronic device of claim 2,
wherein the signal layer includes a plurality of first conductive layers and a plurality of second conductive layers alternately arranged in a first direction with the plurality of first conductive layers, and
wherein the plurality of first conductive layers include a first signal layer disposed at a top of the plurality of first conductive layers and extending across the capacitor area and the ground area in a second direction perpendicular to the first direction.

4. The electronic device of claim 3,
wherein the ground layer includes a plurality of conductive layers,
wherein the plurality of conductive layers of the ground layer includes:
a first ground layer disposed at the top of the plurality of conductive layers, and
a second ground layer disposed below the first signal layer and overlapping at least a portion of the first signal layer, and
wherein the at least one discharge hole extends in the first direction from the first signal layer to the second ground layer.

5. The electronic device of claim 4, wherein the at least one discharge hole is a space surrounded by the first signal layer, the insulation layer, and the second ground layer.

6. The electronic device of claim 4, wherein a length of the first signal layer in the second direction is longer than a length of the first ground layer in the second direction.

7. The electronic device of claim 4, wherein the PCB further includes:
a coating layer of a conductive material covering an externally exposed surface of the first signal layer and a surface of the second ground layer.

8. The electronic device of claim 4, further comprising:
a discharge path composed of the conductive first side frame or the conductive second side frame, the conductive member, the first signal layer, and the second ground layer,
wherein charge accumulated in the electronic device moves along the discharge path through the at least one discharge hole.

9. The electronic device of claim 2,
wherein the ground layer includes a plurality of conductive layers, and
wherein the plurality of conductive layers includes:
a first ground layer disposed at a top of the plurality of conductive layers and extending across the capacitor area and the ground area in a second direction perpendicular to a first direction.

10. The electronic device of claim 9,
wherein the PCB further includes:
a protective layer made of an insulating material disposed on the first ground layer of the ground layer, and
wherein the at least one discharge hole extends in the first direction from the protective layer to the first ground layer.

11. The electronic device of claim 10, wherein the at least one discharge hole is a space surrounded by at least a portion of a plurality of conductive members, the protective layer, and the first ground layer.

12. The electronic device of claim 9,
wherein the signal layer includes:
a plurality of first conductive layers and a plurality of second conductive layers alternately arranged in the first direction with the plurality of first conductive layers, and
wherein the plurality of first conductive layers include a first signal layer disposed at the top of the plurality of first conductive layers, and
wherein a length of the first ground layer in the second direction is longer than a length of the first signal layer in the second direction.

13. The electronic device of claim 9, wherein the at least one discharge hole is disposed below at least a portion of the conductive member.

14. The electronic device of claim 9, wherein the conductive member includes:
a discharge protrusion that protrudes from a side of the conductive member and is located above the at least one discharge hole.

15. The electronic device of claim 9, further comprising:
a discharge path composed of the conductive first side frame or the conductive second side frame, conductive members, and the first ground layer,
wherein charge accumulated in the electronic device moves along the discharge path through the at least one discharge hole.

16. An electronic device comprising:
a first housing including a conductive first side frame;
a second housing including a conductive second side frame;
a flexible display disposed on the first housing and the second housing;
a hinge module rotatably coupled between the first housing and the second housing; and
a printed circuit board disposed on the first housing or the second housing, and including a conductive pad electrically connected to the conductive first side frame or the conductive second side frame, a signal layer, a ground layer, and an insulation layer,
wherein the ground layer includes a plurality of conductive layers, and
wherein at least one of the plurality of conductive layers includes a discharge portion disposed on a same plane as a side surface of the printed circuit board to be visible from an outside.

17. The electronic device of claim 16, wherein the conductive pad includes a body portion and an extension extending from the body portion to an edge of the printed circuit board.

18. The electronic device of claim 17, wherein the discharge portion is spaced apart from an end portion of the extension of the conductive pad on a side surface of the printed circuit board.

19. The electronic device of claim 17, further comprising:
a discharge path constituted of the conductive first side frame or the conductive second side frame, the conductive pad, and the ground layer,
wherein charge accumulated in the electronic device is discharged between the discharge portion and the extension of the conductive pad.

20. An electronic device comprising:
a housing including a conductive side frame; and
a printed circuit board disposed on the housing, and including a conductive member electrically connected to a side frame, a signal layer, a ground layer, and an insulation layer,
wherein the printed circuit board includes:
at least one discharge hole recessed from a surface of the printed circuit board so that the ground layer is visible from an outside, and
forming a gap between the ground layer and any one of the signal layer or the conductive member.
